(19) United States
(12) Patent Application Publication
(10) Pub. No.: US 2026/0066779 A1
(43) Pub. Date: Mar. 5, 2026

(54) CONVERTER

(71) Applicant: STMicroelectronics International N.V., Geneva (CH)

(72) Inventor: Loic BOURGUINE, Chateauneuf Le Rouge (FR)

(73) Assignee: STMicroelectronics International N.V., Geneva (CH)

(21) Appl. No.: 19/304,012

(22) Filed: Aug. 19, 2025

(30) Foreign Application Priority Data
Aug. 29, 2024 (FR) FR2409216

(51) Int. Cl. H02M 3/00; H02M 3/158

(52) U.S. Cl. CPC H02M 3/003; H02M 3/158

(57) ABSTRACT

The present disclosure relates to a voltage converter formed on a GaN-coated substrate, comprising: a first chip including a first e-mode transistor and a first control circuit for the first transistor; and a second chip including a second transistor e-mode and a second control circuit of the second transistor, and being suitable for forwarding the first voltage received from a third control circuit to the second chip; wherein the second chip includes a voltage converter suitable for converting the first voltage into a second voltage, the voltage converter including a first current source used when an output voltage of the converter is below a threshold voltage, and a second current source used when the output voltage is above the threshold voltage.

### CROSS-REFERENCE TO RELATED APPLICATION(S)

This application claims the priority benefit of French patent application number FR2409216, filed on Aug. 29, 2024, entitled “Convertisseur,” which is hereby incorporated by reference to the maximum extent allowable by law.

### BACKGROUND

### Technical Field

The present description relates generally to electronic systems and devices, and in particular to voltage conversion within an electronic system or device. The present description relates more particularly to a converter formed in and on a structure including gallium nitride (GaN).

### Description of the Related Art

Conventionally, electronic systems and devices are formed from silicon substrates, but other semiconductor materials can also be used. In particular, structures including gallium nitride (GaN) can be used.

It would be desirable to be able to improve, at least in part, some aspects of electronic systems and devices formed from and on structures including gallium nitride.

### BRIEF SUMMARY

There is a need for electronic systems and devices formed in and on structures including gallium nitride.

There is a need for voltage converters formed in and on structures including gallium nitride.

One embodiment overcomes some or all of the drawbacks of known voltage converters formed in and on structures including gallium nitride.

One embodiment provides a more efficient voltage converter formed in and on structures including gallium nitride.

One embodiment provides a voltage converter with a more efficient structure of the half-bridge type.

One embodiment provides a voltage converter including two chips, a first chip suitable for handling low voltages and a second chip suitable for handling high voltages.

One embodiment provides such a voltage converter wherein control voltages are supplied only to the first chip, these control voltages being forwarded to the second chip via the first chip.

According to a first aspect, one embodiment provides a voltage converter including a more efficient voltage shifter circuit enabling control voltages to be forwarded from the first chip to the second chip.

One embodiment provides such a voltage converter using several current sources depending on the value of an output voltage of the converter.

According to a second aspect, one embodiment provides a circuit allowing high-voltage signals to be converted to low-voltage signals.

According to a third aspect, one embodiment provides a voltage converter formed from two identical configurable chips, each of which may be the first or second chip.

One embodiment provides a voltage converter formed in and on a monolithic semiconductor substrate having a face coated by a gallium nitride layer, including:
a first chip including a first e-mode-type HEMT power transistor, and a first control circuit of the first transistor; and
a second chip including a second e-mode-type HEMT power transistor, and a second control circuit of the second transistor, and being suitable for forwarding at least one first voltage received from a third control circuit to the second chip;
wherein the second chip includes a first voltage shifter circuit suitable for converting the at least one first voltage into a second voltage,
the first voltage shifter circuit including a first current source suitable for being used when a third output voltage of the converter is less than a fourth threshold voltage, and a second current source suitable for being used when the third output voltage is higher than the fourth threshold voltage.

According to one embodiment, the first and second current sources are used to provide a control voltage to the first transistor.

According to one embodiment, the fourth threshold voltage is between −5 and 0 V.

According to one embodiment, the fourth threshold voltage is equal to −2 V.

According to one embodiment, the first chip is suitable for receiving high voltages, and the second chip is suitable for receiving low voltages.

According to one embodiment, the first chip further includes a fourth voltage adapter circuit suitable for converting at least one fifth voltage of the first chip into a sixth diagnosis voltage to forward it to the second chip, the fourth voltage adapter circuit including an oscillator being configured to oscillate the sixth voltage when the fifth voltage is at a first state.

According to one embodiment, the oscillator is configured not to oscillate the sixth voltage when the fifth voltage is at a second state different from the first state.

According to one embodiment, the first and second chips are identical chips.

According to one embodiment, the first and second chips comprise each a configuration terminal allowing them to define their function in the converter.

According to one embodiment, the converter is a switched-mode power supply.

According to one embodiment, the converter is a switched-mode power supply of the boost-converter type.

Another embodiment provides a method for converting a seventh input voltage into a third output voltage using a voltage converter formed in and on a monolithic semiconductor substrate having a face coated by a gallium nitride layer, including:
a first chip including a first e-mode-type HEMT power transistor, and a first control circuit of the first transistor; and
a second chip including a second e-mode-type HEMT power transistor, and a second control circuit of the second transistor, and being suitable for forwarding at least one first voltage received from a third control circuit to the second chip;
wherein the second chip includes a first voltage adapter circuit suitable for converting the at least one first voltage into a second voltage,
the first voltage shifter circuit including a first current source suitable for being used when a third output voltage of the converter is less than a fourth threshold voltage, and a second current source suitable for being used when the third output voltage is higher than the fourth threshold voltage.

Another embodiment provides a method for manufacturing a voltage converter, including:
a first chip including a first e-mode-type HEMT power transistor, and a first control circuit of the first transistor; and
a second chip including a second e-mode-type HEMT power transistor, and a second control circuit of the second transistor,
including two identical steps of manufacturing the first and second chips.

According to one embodiment, the method further includes a step of configuring the first and second chips which follows the two manufacturing steps.

According to one embodiment, during the configuring step, a configuration terminal of the first and second chips is used.

According to one embodiment, a method includes driving a first HEMT power transistor of a first chip with a first control circuit of the first chip of a voltage converter and driving a second HEMT power transistor of a second chip with a second control circuit of the second chip of the voltage converter. The first and second HEMT power transistor are coupled together in a half bridge configuration. The first chip is a high side chip and the second chip is a low side chip. The method includes receiving, with the second chip, first control signals for the first chip from a third control circuit external to the first and second chips, receiving, with the second chip, second control signals for the second chip from the third control circuit, providing the first control signals from the second chip to the first chip, receiving an input voltage of the voltage regulator at the second chip, and generating an output voltage of the voltage regulator at an output of the half bridge circuit.

According to an embodiment, the method includes providing diagnostic signals from the first chip to the second chip.

According to an embodiment, the method includes providing the diagnostic signals from the second chip to the third control circuit.

According to an embodiment, the method includes receiving high voltages at the first chip and receiving low voltages at the second chip.

According to an embodiment, the method includes generating a first current with a first current source of the first chip.

According to an embodiment, the method includes generating a second current with a second current source of the first chip.

According to an embodiment, a method includes forming a first chip of a voltage converter, including forming a first HEMT power transistor in the first chip and forming a first driver circuit of the first HEMT transistor in the first chip. The method includes forming a second chip of the voltage converter including forming a second HEMT power transistor in the second chip and forming a second driver circuit of the second HEMT transistor in the second chip. The method includes coupling the first and second HEMT transistors together in a half bridge configuration and coupling a third control circuit to the second chip. The third control circuit is configured to provide to the second chip first control signals for the first chip, to provide second control signal to the second chip for controlling the second chip, and to provide an input voltage of the voltage regulator to the second chip. The voltage regulator is configured to provide an output voltage of the voltage regulator from a joint terminal of the first and second HEMT transistors.

According to an embodiment, the method includes forming the first and second chips in two identical manufacturing steps.

According to an embodiment, the method includes configuring the first and second chips following the two manufacturing steps.

### BRIEF DESCRIPTION OF THE SEVERAL VIEWS OF THE DRAWINGS

The foregoing features and advantages, as well as others, will be described in detail in the following description of specific embodiments given by way of illustration and not limitation with reference to the accompanying drawings, in which:

FIG. 1 illustrates, very schematically, a structure including gallium nitride;

FIG. 2 includes two views (A) and (B) illustrating a first type of transistor formed in and on a structure including gallium nitride;

FIG. 3 illustrates two views (A) and (B) illustrating a second type of transistor formed in a structure including gallium nitride;

FIG. 4 illustrates schematically and under block form an embodiment of a voltage converter;

FIG. 5 illustrates a practical example of the embodiment shown in FIG. 4;

FIG. 6 illustrates an embodiment of part of the converter shown in FIG. 4;

FIG. 7 illustrates an embodiment of a voltage shifter circuit of the embodiment shown in FIG. 6;

FIG. 8 illustrates in more detail an embodiment of a voltage shifter circuit of the embodiment shown in FIG. 6;

FIG. 9 illustrates another voltage converter circuit of the embodiment shown in FIG. 6; and

FIG. 10 illustrates, very schematically, a practical implementation of the embodiment shown in FIG. 4.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front,” “back,” “top,” “bottom,” “left,” “right,” etc., or to relative positional qualifiers, such as the terms “above,” “below,” “higher,” “lower,” etc., or to qualifiers of orientation, such as “horizontal,” “vertical,” etc., reference is made to the orientation shown in the figure.

Unless specified otherwise, the expressions “around,” “approximately,” “substantially” and “in the order of” signify within 10%, and preferably within 5%.

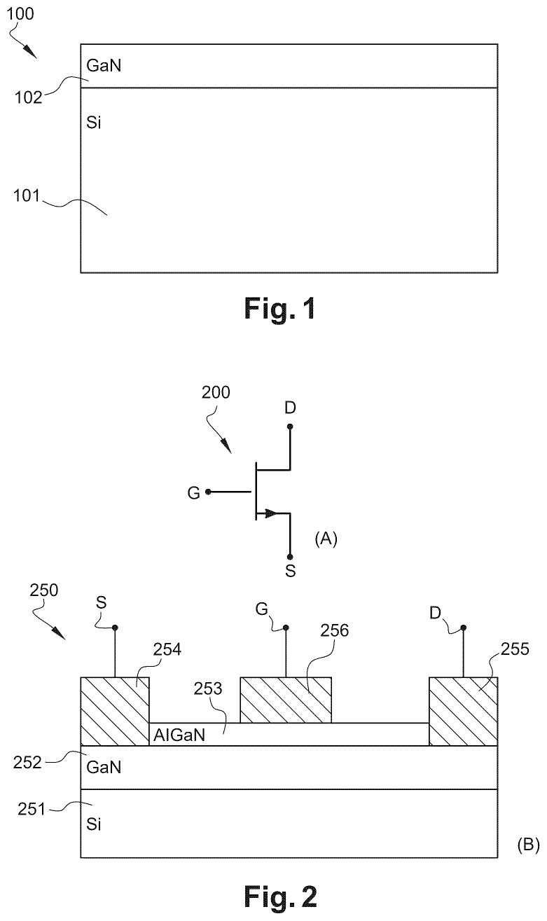

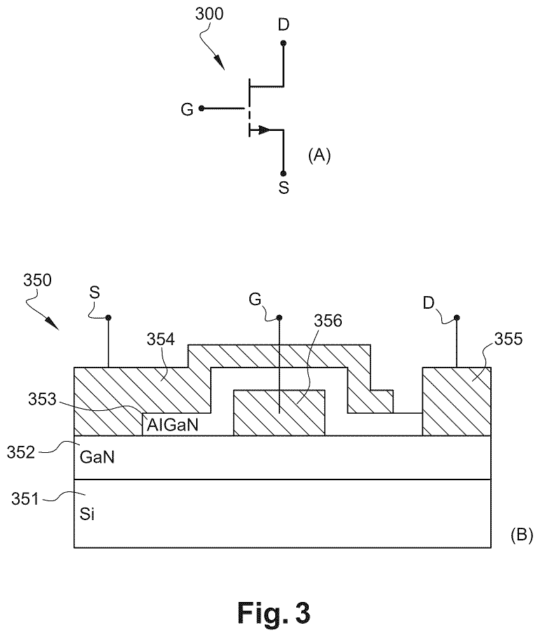

The embodiments described hereinafter relate to electronic systems and devices formed in and on structures including gallium nitride, an example of such a structure is described in connection with FIG. 1. Using such structures does not allow using conventional electronic components, and in particular, does not allow using electronic components using PN junctions such as diodes, MOSFET-type transistors, etc. However, high electron mobility transistors can be used. Two types of these transistors are described in connection with FIGS. 2 and 3.

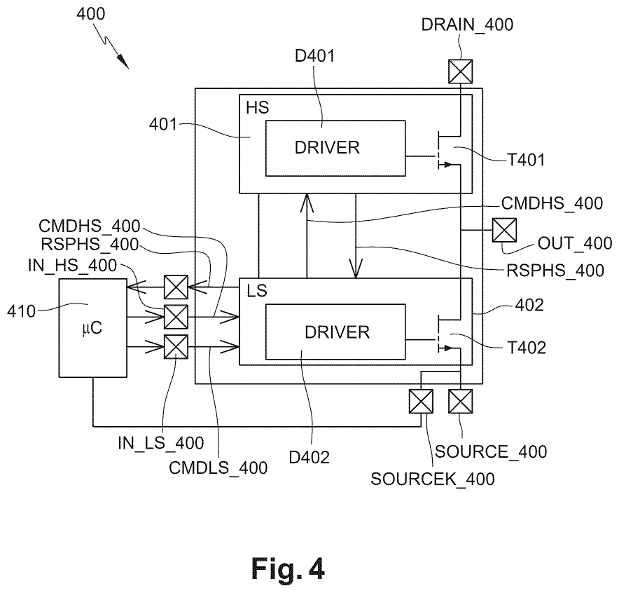

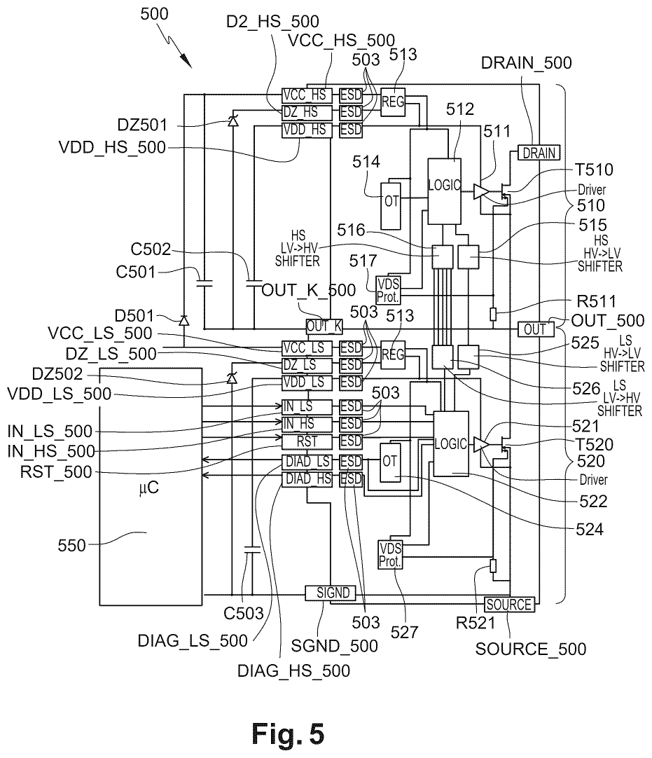

The embodiments described hereinafter relate more particularly to a voltage converter formed in and on such structures. More specifically, this is a voltage converter using a structure of the half-bridge type, described in connection with FIGS. 4 and 5. A first aspect of these embodiments relates to a voltage shifter circuit, or voltage offset circuit, allowing voltages to be forwarded from a low-voltage chip to a high-voltage chip. A second aspect of these embodiments relates to a conversion circuit allowing signals to be forwarded from the high-voltage chip to the low-voltage chip. A third aspect of these embodiments relates to a practical example embodiment of a voltage converter and its manufacturing method.

In addition, the embodiments described above are particularly suitable for use in any type of industrial market where voltage conversion is called for. More particularly, such a voltage converter circuit may be intended for:
the automotive industry, for example in the field of automotive electrification or in the field of Advanced Driver Assistance Systems (ADAS);
the industrial industry, for example in the field of green energy, infrastructure electrification, the Internet of Things (IOT) and Smart Home, where electricity and energy consumption and data exchange are key elements;
the personal electronics industry, for example in the fields of mobile telephony and the Internet of Things (IOT), as well as in the field of broadband interfaces; and
the communications equipment, computer and peripherals industry, for example in the field of infrastructure and data centers, and in the field of Low Earth Orbit (LEO) satellites.

In particular, these embodiments can be used in the automotive industry for energy conversion. More specifically, these voltage converters can be used in vehicle battery chargers, and electric vehicle chargers.

FIG. 1 is a sectional view illustrating, very schematically, a semiconductive structure 100 including gallium nitride.

The structure 100 is generally formed of a substrate 101 (Si) made of a semiconductor material, e.g., a silicon substrate, one face of which being covered with a layer 102 (GaN) made of gallium nitride (GaN). Layer 102 is between 0.5 and 5 μm thick.

When structure 100 is used as the basis for an electronic system or device, electronic components are formed in and on layer 102. Metallization levels can further be formed on layer 102.

FIG. 2 includes two views (A) and (B) illustrating a first type of transistor 200 formed in a structure including gallium nitride. View (A) illustrates a circuit diagram of the transistor 200, and view (B) illustrates a sectional view of a structure 250 forming the transistor 200.

Transistor 200 is a High Electron Mobility Transistor (HEMT), also referred to as a MOdulated-Doping Field-Effect Transistor (MODFET). Hereinafter, a high-mobility electron transistor is referred to as HEMT transistor.

An HEMT transistor, such as transistor 200, includes a gate terminal, denoted G in FIG. 2, a source terminal, denoted S in FIG. 2, and a drain terminal, denoted D in FIG. 2.

In addition, transistor 200 is a depletion-mode HEMT, hereinafter referred to as an HEMT transistor of the d-mode type, or d-mode transistor. According to another designation, transistor 200 is an HEMT transistor of the normally-ON type, or normally-ON HEMT transistor, or normally-ON transistor. The circuit diagram of transistor 200 shown in view (A) is the circuit diagram that will be used in all subsequent figures to illustrate a d-mode or normally-ON transistor.

In practice, the transistor 200 can be obtained by a structure 250 formed from a structure of the type of structure 100 described in connection with FIG. 1. Thus, structure 250 includes a substrate 251 (Si) made of a conductive material, such as silicon, one face of which being covered by a layer 252 (GaN) made of gallium nitride. The gallium nitride layer 252 is partially covered by a layer 253 (AlGaN) made of aluminum-gallium nitride. A connection terminal 254 forms the source recovery contact S of transistor 200. Connection terminal 254 is formed on a portion of layer 252 not covered by layer 253. A connection terminal 255 forms the drain recovery contact D of transistor 200. Connection terminal 255 is formed on a portion of layer 252 that is not covered by layer 253. A connection terminal 256 forms the gate recovery contact G of transistor 200. Connection terminal 256 is formed on a portion of layer 253, and is arranged between connection pads 254 and 255.

Transistor 200 operates as follows. When the gate G of transistor 200 is left floating, or a positive voltage is applied between its gate G and source S, transistor 200 is conductive, hence its name normally ON. To “close” transistor 200, i.e., make it non-conductive, a negative voltage is applied between its gate G and its source S.

FIG. 3 includes two views (A) and (B) illustrating a second type of transistor 300 formed in a structure including gallium nitride. View (A) shows a circuit diagram of transistor 300, and view (B) shows a sectional view of a structure 350 forming transistor 300.

Like the transistor 200 described in connection with FIG. 2, transistor 300 is a high-mobility electron transistor, or HEMT transistor. Transistor 300 includes a gate terminal, denoted G in FIG. 3, a source terminal, denoted S in FIG. 3, and a drain terminal, denoted D in FIG. 3.

In addition, and in contrast to the transistor 200 of FIG. 2, transistor 300 is an enhancement mode HEMT transistor, hereinafter referred to as an HEMT transistor of the e-mode type, or e-mode transistor. According to another designation, transistor 300 is an HEMT transistor of the normally-OFF type, or normally-OFF HEMT transistor, or normally OFF transistor. The circuit diagram of transistor 300 shown in view (A) is the circuit diagram that will be used in all subsequent figures to illustrate an e-mode or normally-OFF transistor.

In practice, the transistor 300 can be obtained by a structure 350 formed from a structure of the type of structure 100 described in connection with FIG. 1. Thus, structure 350 includes a substrate 351 (Si) made of a conductive material, such as silicon, one face of which is covered by a layer 352 (GaN) made of gallium nitride. The gallium nitride layer 352 is partially covered by a layer 353 (AlGaN) made of aluminum-gallium nitride. A connection terminal 354 forms the source recovery contact S of transistor 300. Connection terminal 354 is formed on a portion of layer 352 not covered by layer 353. A connection terminal 355 forms the drain recovery contact D of transistor 300. Connection terminal 355 is formed on a portion of layer 352 that is not covered by layer 353. A connection terminal 356 forms the gate recovery contact G of transistor 300. Connection terminal 356 is formed between layer 352 and layer 353, and is disposed between connection pads 354 and 355. In addition, a portion of connection pad 354 overlaps the portion of layer 353 covering connection pad 356, as shown in view (B) of FIG. 3.

Transistor 300 operates as follows. When the gate G of transistor 300 is left floating, or when a negative voltage is applied between its gate G and source S, transistor 300 is non-conducting or OFF, hence its name normally-OFF HEMT transistor. To “open” transistor 300, i.e., make it conductive, a positive voltage is be applied between its gate G and its source S.

FIG. 4 illustrates an embodiment of a voltage converter 400 and its outer control circuit 410 (μC).

The voltage converter 400, or voltage converter circuit, is suitable for converting a first received voltage to a second voltage supplied between a terminal OUT_400 and the reference terminal SOURCE_400. According to one example, the converter 400 is a switched-mode power supply, for example a switched-mode power supply of the boost-converter type. More particularly, the voltage converter 400 has a half-bridge structure, i.e., a structure using two power transistors arranged in series and their driver circuits.

According to one embodiment, the converter 400 includes at least two chips, a chip 401 (HS) receiving high voltages and a chip 402 (LS) receiving low voltages. Chip 401 is also referred to as a high-voltage chip, and chip 402 is also referred to as a low-voltage chip. Are considered herein as low voltages, voltages between 0 and 20 V, preferably between 5 and 15 V. Are considered herein as high voltages, voltages higher than 350 V, preferably between 400 and 650 V.

Chip 401 includes an HEMT power transistor T401 of the e-mode type. A drain terminal of transistor T401 is coupled, preferably connected, to a terminal DRAIN_400 of converter 400. A source terminal of the transistor T401 is coupled, preferably connected, to the terminal OUT_400 of the converter 400.

Chip 401 further includes a driver circuit D401 (DRIVER) for transistor T401. An output terminal of the driver circuit D401 is coupled, preferably connected, to the gate terminal of transistor T401.

Chip 402 includes an HEMT power transistor T402 of the e-mode type. A drain terminal of transistor T402 is coupled, preferably connected, to a terminal OUT_400 of converter 400. A source terminal of the transistor T402 is coupled, preferably connected, to the terminal SOURCE_400 of the converter 400.

Chip 402 further includes a driver circuit D402 (DRIVER) for transistor T402. An output terminal of the driver circuit D402 is coupled, preferably connected, to the gate terminal of the transistor T402.

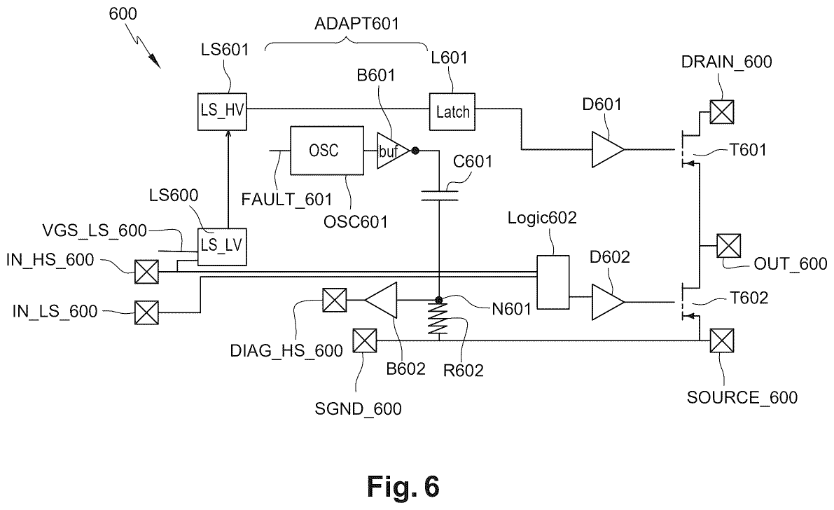

The converter 400 is suitable to be controlled by the control circuit 410. According to one embodiment, the control circuit 410 is suitable for supplying control voltages intended to the chips 401 and 402 of the converter 400, but is coupled only to the chip 402. More particularly, chip 402 includes a terminal IN_LS_400 intended to receive control voltages CMDLS_400 for itself, and a terminal IN_HS_400 intended to receive control voltages CMDLS_400 for chip 401. According to one embodiment, the chip 401 includes circuitry allowing the voltage levels of the control voltages CMDHS_400 of the control circuit 410 to be adapted so that these control voltages CMDHS_400 are used by the chip 402. Examples of such circuits are described in connection with FIGS. 6 to 8.

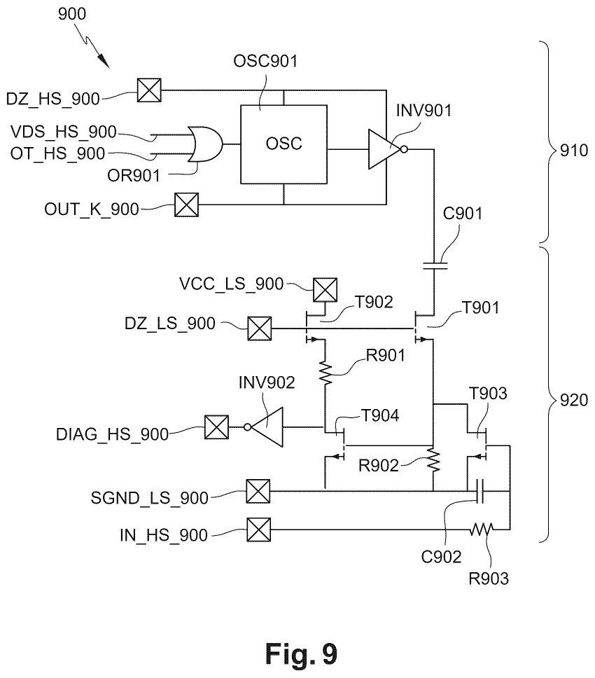

The control circuit 410 is further suitable for receiving voltages from the chip 402, such as diagnostic voltages RSPHS_400. To this end, and according to one embodiment, chip 402 includes circuitry allowing diagnostic voltages RSPHS_400 to be converted so that chip 401 can receive them and forward them to control circuit 410. Examples of such circuits are described in connection with FIGS. 6 and 9.

A method for converting voltage using the converter 400 is as follows. A voltage to be converted is supplied between terminals IN_400 and SOURCE_400, and a converted voltage is output between terminals OUT_400 and SOURCE_400. A DC potential is supplied to terminal DRAIN_400. Transistors T401 and T402 are made alternately conducting and non-conducting by their driver circuits according to the commands supplied by the control circuit.

FIG. 5 illustrates a practical example embodiment of voltage converter 400 and its control circuit 410 (μC) described in connection with FIG. 4. More particularly, FIG. 5 illustrates a converter 500 and its control circuit 550 (μC).

The converter 500 is formed in and on a structure of the type of structure 100 described in connection with FIG. 1. More particularly, the converter 500 includes a majority of its components formed on such a structure, and further includes a minority of components formed on a semiconductor structure including no gallium nitride (GaN).

The converter 500 includes:
a terminal DRAIN_500 (DRAIN);
a terminal OUT_500 (OUT);
a terminal SOURCE_500 (SOURCE);
a terminal SGND_500 (SGND);
a terminal VCC_HS_500 (VCC_HS);
a terminal DZ_HS_500 (DZ_HS);
a terminal VDD_HS_500 (VDD_HS);
an output terminal OUT_500 (OUT) suitable for supplying a converted voltage;
an output terminal OUT_K_500 (OUT_K);
a terminal VCC_LS_500 (VCC_LS);
a terminal DZ_LS_500 (DC_LS);
a terminal VDD_LS_500 (VDD_LS);
a terminal IN_LS_500 (VCC_LS);
a terminal IN_HS_500 (IN_HS);
a terminal RST_500 (RST);
a terminal DIAG_LS_500 (DIAG_LS); and
a terminal DIAG_HS_500 (DIAG_HS).

The converter 500 further includes a chip 510 of the type of chip 401 described in connection with FIG. 4, and a chip 520 of the type of chip 402 described in connection with FIG. 4. These chips 510 and 520 include components which are coupled to the various converter terminals described above, for example, via electrostatic discharge protection circuits 503 (ESD).

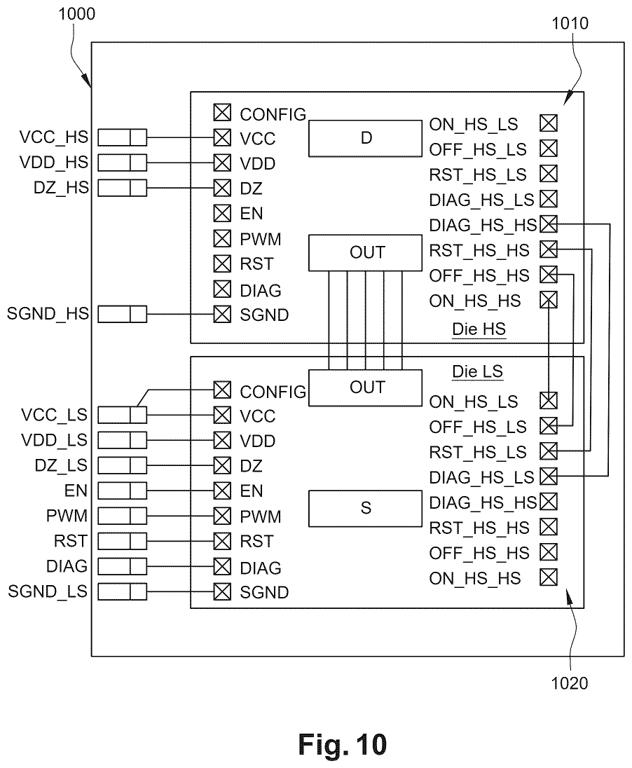

The chips 510 and 520 include similar components. More particularly, the chips 510 and 520 may be identical chips which further include a configuration terminal (not shown in FIG. 5). This can have the advantage of avoiding compatibility problems due to differences in manufacturing methods. This aspect of the disclosure is described in more detail in connection with FIG. 10.

Chip 510 is a low-high voltage chip including a transistor T510 of the type of transistor T401 described in connection with FIG. 4. In other words, transistor T510 is an HEMT transistor of the e-mode type. A drain terminal of transistor T510 is coupled, preferably connected, to the terminal DRAIN_500 of converter 500. A first source terminal of transistor T510 is coupled, preferably connected, to the terminal OUT_500 of converter 500. A second source terminal of transistor T510 is coupled to the terminal OUT_500 of converter 500 via a resistor R511.

The chip 510 further includes a driver circuit of transistor T510 of the type of driver circuit D401 described in connection with FIG. 4. The driver circuit of transistor T510 includes various elements, in which:
a gate driver circuit 511 (DRIVER) for transistor T510;
a set of logic circuits 512 (LOGIC);
a voltage regulation circuit 513 (REG);
an overtemperature detection circuit 514 (OT);
a voltage matching circuit 515 (HS HV->LV Shifter) converting high voltages to low voltages;
a voltage conversion circuit 516 (HS LV->HV Shifter) converting low voltages to high voltages; and
an overvoltage protection circuit 517 (VDS Prot.).

Gate driver circuit 511 includes an output coupled, preferably connected, to a gate terminal of transistor T510. Circuit 511 receives control voltages from the set of logic circuits 512. Circuit 511 is supplied by a potential served by terminal VDD_HS_500, and is referenced to the potential of output terminal OUT_500.

The set of logic circuits 512 receives voltages from circuits 514 to 517, and combines these voltages to provide a control voltage to gate driver circuit 511 of transistor T510. Set 512 is supplied by a potential served by voltage regulator circuit 513.

Voltage regulation circuit 513 includes two input terminals coupled to terminals VCC_HS_500 and DZ_HS_500, for example, via electrostatic discharge protection circuits 503. Circuit 513 includes two output terminals, one coupled to terminal VDD_HS_500, for example via a circuit 503, and the other providing the supply potential for gate driver circuit 511.

The overtemperature detection circuit 514 is a circuit allowing an abnormal temperature rise within the converter 500 to be detected, and in particular within the chip 510. The circuit 514 is powered by the regulation circuit 513, and provides an overtemperature detection voltage to the set of logic circuits 512.

The voltage matching circuit 515 is, as previously mentioned, suitable for converting high voltages to low voltages. More particularly, voltage matching circuit 515, or voltage adaptor circuit 515, is suitable for converting voltages used by chip 510 to voltages usable by chip 520. Circuit 515 is therefore suitable for receiving, from the set of logic circuits 512, voltages to be forwarded to chip 520, and for forwarding converted voltages to chip 520. One specific embodiment of circuit 515 is described in connection with FIG. 9.

The voltage conversion circuit 516 is, as previously mentioned, suitable for converting low voltages to high voltages. More particularly, the voltage conversion circuit 516, or voltage converter circuit 516, or voltage shifter circuit 516, is suitable for converting voltages used by the chip 520 to voltages usable by the chip 510. The circuit 516 is thus suitable for receiving voltages from the chip 510, and for forwarding converted voltages to the set of logic circuits 512.

The protection circuit 517 is suitable for detecting any overvoltage or overcurrent that may occur at transistor T510. To this end, circuit 517 is powered by a supply potential provided by the voltage regulation circuit 513. Circuit 517 is coupled, preferably connected, to the second source terminal of transistor T510. Circuit 517 provides a detection voltage to the set of logic circuits 512.

The chip 520 is a low-voltage chip including a transistor T520 of the type of the transistor T402 described in connection with FIG. 4. In other words, transistor T520 is an HEMT transistor of the e-mode type. A drain terminal of transistor T520 is coupled, preferably connected, to output terminal OUT_500 of converter 500. A first source terminal of transistor T520 is coupled, preferably connected, to the terminal SOURCE_500 and to the terminal SGND_500 of converter 500. A second source terminal of transistor T520 is coupled to the terminal OUT_500 of converter 500 via a resistor R521.

The chip 520 further includes a driver circuit of transistor T520 of the type of driver circuit D402 described in connection with FIG. 4. The driver circuit of transistor T520 includes various elements, in which:
a gate driver circuit 521 (DRIVER) for transistor T520;
a set of logic circuits 522 (LOGIC);
a voltage regulation circuit 523 (REG);
an overtemperature detection circuit 524 (OT);
a voltage conversion circuit 525 (LS HV->LV Shifter) converting high voltages to low voltages;
a voltage conversion circuit 526 (LS LV->HV Shifter) converting low voltages to high voltages; and
a protection circuit 527 (VDS Prot.).

Gate driver circuit 521 includes an output coupled, preferably connected, to a gate terminal of transistor T520. Circuit 521 receives control voltages from the set of logic circuits 522. Circuit 521 is supplied by a potential served by terminal VDD_LS_500, and is referenced to the potential of output terminal SOURCE_500.

The set of logic circuits 522 receives voltages from circuits 524 to 527 and from terminals IN_LS_00, IN_HS_500, RST_500, DIAG_LS_500, and DIAG_HS_500, for example via circuits 503. The set of logic circuits 522 combines these voltages to supply a control voltage to gate driver circuit 21 of transistor T520. The set 522 is supplied by a potential served by voltage regulator circuitry 523.

Voltage regulation circuit 523 includes two input terminals coupled to terminals VCC_LS_500 and DZ_LS_500, for example, via electrostatic discharge protection circuits 503. Circuit 523 includes two output terminals, one coupled to terminal VDD_LS_500, for example via a circuit 503, and the other providing the supply potential for gate driver circuit 521.

The overtemperature detection circuit 524 is a circuit allowing an abnormal rise in temperature to be detected within the converter 500, and in particular within the chip 520. The circuit 524 is supplied by the regulation circuit 523, and provides an overtemperature detection voltage to the set of logic circuits 522 and to the terminal DIAG_LS_500.

The voltage conversion circuit 525 is, as previously mentioned, suitable for converting high voltages to low voltages. More particularly, the voltage conversion circuit 525, or voltage converter circuit 525, is suitable for converting voltages provided by the chip 510 to voltages usable by the chip 520. Circuit 525 is thus suitable for receiving, from chip 520, voltages to be forwarded to chip 510, and for forwarding converted voltages to the set of logic circuits 520.

The voltage conversion circuit 526 is, as previously mentioned, suitable for converting low voltages to high voltages. More particularly, voltage conversion circuit 526, or voltage converter circuit 526, or voltage shifter circuit 526, is suitable for converting voltages used by chip 520 to voltages usable by chip 510. Circuit 526 is thus suitable for receiving voltages from the set of logic circuits 522, and for forwarding converted voltages to chip 510. Embodiments of circuits 526 are described in connection with FIGS. 6 to 8.

The protection circuit 527 is suitable for detecting overvoltage or overcurrent that may occur at transistor T520. To this end, circuit 527 is supplied with a supply potential provided by the voltage regulation circuit 523. Circuit 527 is coupled, preferably connected, to the second source terminal of transistor T520. Circuit 527 provides a detection voltage to the set of logic circuits 522.

As previously mentioned, the converter 500 further includes components which are not formed on a structure of the type of structure 100 described in connection with FIG. 1. These components are diodes and capacitors which cannot be formed on such a structure.

Converter 500 includes a diode D501 coupling terminals VCC_HS_500 and VCC_LS_500. More particularly, a cathode terminal of diode D501 is coupled, preferably connected, to terminal VCC_HS_500, and an anode terminal of diode D501 is coupled, preferably connected, to terminal VCC_LS_500.

Converter 500 further includes a capacitor C501 coupling terminals VCC_HS_500 and OUT_K_500. More particularly, a first terminal of capacitor C501 is coupled, preferably connected, to terminal VCC_HS_500, and a second terminal of capacitor C501 is coupled, preferably connected, to terminal OUT_K_500.

Converter 500 further includes a Zener diode DZ501 coupling terminals DZ_HS_500 and OUT_K_500. More particularly, a cathode terminal of diode DZ501 is coupled, preferably connected, to terminal DZ_HS_500, and an anode terminal of diode DZ501 is coupled, preferably connected, to terminal OUT_K_500.

Converter 500 further includes a capacitor C502 coupling terminals VDD_HS_500 and OUT_K_500. More particularly, a first terminal of capacitor C502 is coupled, preferably connected, to terminal VDD_HS_500, and a second terminal of capacitor C502 is coupled, preferably connected, to terminal OUT_K_500.

Converter 500 further includes a Zener diode DZ502 coupling terminals DZ_LS_500 and SGND_500. More particularly, a cathode terminal of diode DZ502 is coupled, preferably connected, to terminal DZ_LS_500, and an anode terminal of diode DZ502 is coupled, preferably connected, to terminal SGND_500.

Converter 500 further includes a capacitor C503 coupling terminals VDD_LS_500 and SGND_500. More particularly, a first terminal of capacitor C503 is coupled, preferably connected, to terminal VDD_LS_500, and a second terminal of capacitor C503 is coupled, preferably connected, to terminal SGND_500.

In addition, and as previously mentioned, FIG. 5 illustrates the control circuit 550 of the converter 500. According to one example, the control circuit 550 is a processor, a microprocessor, a controller, or a microcontroller. According to one embodiment, control circuit 550 is suitable for communicating only with chip 520, and is suitable for handling only low voltages, like chip 520. Thus, control circuit 550 is suitable for supplying control voltages intended for chip 520 at terminal IN_LS_500, and for supplying control voltages intended for chip 510 at terminal IN_HS_500. Control circuit 550 is further suitable for supplying a reset voltage to terminal RST_500. The control circuit 550 is further suitable for receiving sense voltages from the chip 520 via the terminal DIAG_LS_500, and for receiving sense voltages from the chip 510 via the terminal DIAG_HS_500. The control circuit is also referenced to terminal SGND_500. According to an alternative embodiment, it is the converter 500 that is referenced to a reference potential provided by the control circuit 550.

FIG. 6 illustrates a circuit 600 illustrating part of a voltage converter circuit of the type of converter 400 described in connection with FIG. 4 or converter 500 described in connection with FIG. 5.

Circuit 600 includes:
a terminal DRAIN_600 (DRAIN) of the type of the terminal DRAIN_400 described in connection with FIG. 4, or of the type of the terminal DRAIN_500 described in connection with FIG. 5;
a terminal OUT_600 (OUT) of the type of the terminal OUT_400 described in connection with FIG. 4, or of the type of the terminal OUT_500 described in connection with FIG. 5;
a terminal SOURCE_600 (SOURCE) of the type of the terminal SOURCE_400 described in connection with FIG. 4, or of the type of the terminal SOURCE_500 described in connection with FIG. 5;
a terminal SGND_600 (SGND) of the type of the terminal SOURCEK_400 described in connection with FIG. 4, or of the type of the terminal SGND_500 described in connection with FIG. 5;
a terminal IN_LS_600 (VCC_LS) of the type of the terminal IN_LS_500 described in connection with FIG. 5;
a terminal IN_HS_600 (IN_HS) of the type of the terminal IN_HS_500 described in connection with FIG. 5; and
a terminal DIAG_HS_600 (DIAG_HS) of the type of the terminal DIAG_HS_500 described in connection with FIG. 5.

Like the converters 400 and 500, the circuit 600 includes two HEMT power transistors T601 and T602 of the e-mode type. More particularly, transistor T601 is of the type of transistor T401 or transistor T510, and transistor T602 is of the type of transistor T402 or transistor T520. Thus, a drain terminal of transistor T601 is coupled, preferably connected, to terminal DRAIN_600, and a source terminal of transistor T601 is coupled, preferably connected, to terminal OUT_600. A drain terminal of transistor T602 is coupled, preferably connected, to terminal DRAIN_600, and a source terminal of transistor T602 is coupled, preferably connected, to terminal OUT_600.

Like the converters 400 and 500, the circuit 600 includes circuits for driving the transistors T601 and T602. Only some parts of these driving circuits are illustrated.

In particular, the circuit for driving the transistor T601 includes:
a gate driver circuit D601 of the type of gate driver circuit D401 described in connection with FIG. 4, or of the type of gate driver circuit 511 described in connection with FIG. 5;
a flip-flop L601;
a voltage shifter circuit LS601 (LS_HV) of the type of voltage shifter circuit 516 described in connection with FIG. 5; and
a voltage adapter circuit ADAPT601 of the type of voltage adapter circuit 515 described in connection with FIG. 5.

The gate driver circuit D601 includes an output, coupled, preferably connected, to the gate terminal of transistor T601. An input of this circuit D601 is coupled, preferably connected, to an output of the flip-flop L601. An input of the flip-flop L601 is coupled, preferably connected, to the output of the voltage shifter circuit LS601.

The voltage adapter circuit ADAPT601 is suitable for receiving, as input, a fault detection signal FAULT_601 and for converting it to a fault detection signal that can be interpreted by the circuit for driving the transistor T602. To this end, the circuit ADAPT601 includes an oscillator OSC601 (OSC), a buffer circuit B601 (buf), and a capacitor C601. An example of the circuit ADAPT601 is described in more detail in connection with FIG. 9.

Oscillator OSC601 receives as input the fault detection signal FAULT_601, and outputs an oscillating signal. More particularly, when signal FAULT601 is in a first state, e.g., a high state, oscillator OSC601 outputs an oscillating signal, or oscillating voltage, and when signal FAULT_601 is in a second state, different from the first state, e.g., a low state, oscillator OSC601 outputs a constant signal, i.e., a signal that does not exhibit oscillation. Alternatively, when signal FAULT601 is in a second state, oscillator OSC601 can output an oscillating signal, having a frequency different from the signal provided when signal FAULT_601 is in the first state.

Buffer circuit B601 receives as input the signal supplied by oscillator OSC601, and includes an inverting output coupled, preferably connected, to a first terminal of capacitor C601. A second terminal of capacitor C602 is coupled, preferably connected, to node N601.

Similarly, the circuit for driving transistor T602 includes:
a gate driver circuit D602 of the type of gate driver circuit D402 described in connection with FIG. 4 or of the type of gate driver circuit 521 described in connection with FIG. 5;
a logic circuit set Logic602 of the type of logic circuit set 522 described in connection with FIG. 5;
a voltage shifter circuit LS602 (LS_LV) of the type of voltage shifter circuit 526 described in connection with FIG. 5; and
a buffer circuit B602; and
a resistor R602.

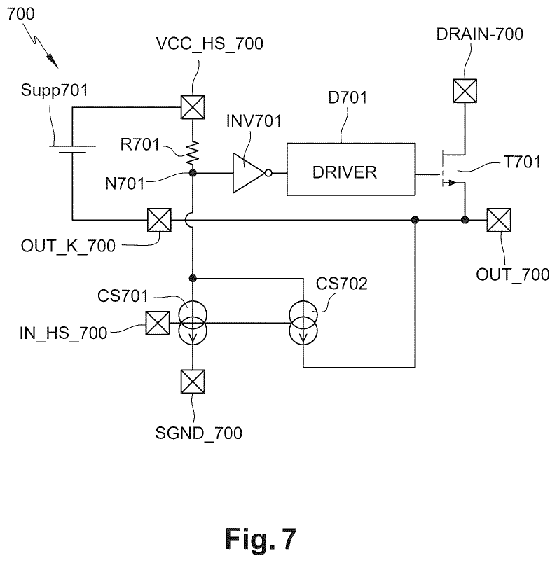

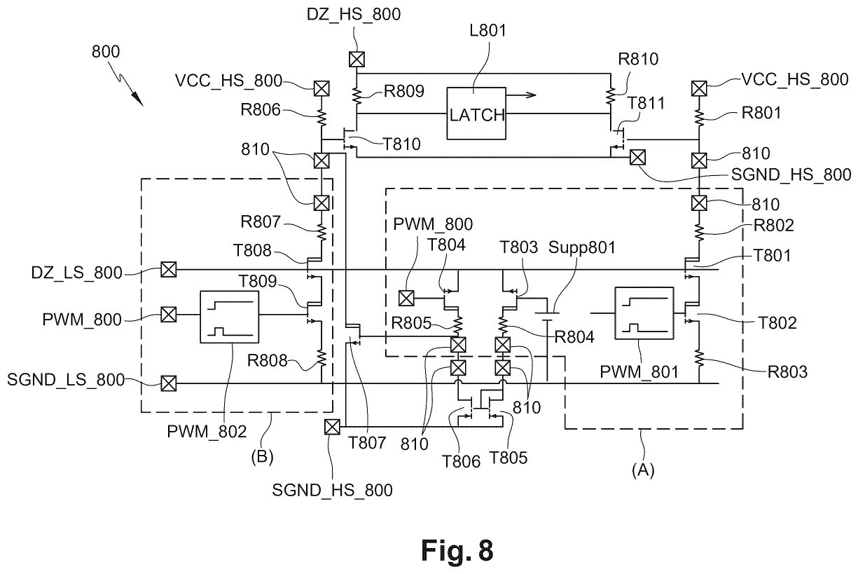

The gate driver circuit D602 includes an output coupled, preferably connected, to the gate terminal of transistor T602. An input of this circuit D602 is coupled, preferably connected, to an output of the logic circuit set Logic602. A first input of the logic circuit set Logic602 is coupled, preferably connected, to the terminal IN_HS_600. A second input of the logic circuit set Logic602 is coupled, preferably connected, to the terminal IN_LS_600. The voltage shifter circuit LS601 includes a first input coupled, preferably connected, to the terminal IN_HS_600, and a second input receiving a potential VGS_LS_602. Examples of the circuit LS602 are described in more detail in connection with FIGS. 7 and 8.

Buffer circuit B602 includes an input coupled, preferably connected, to node N601, and includes an output coupled, preferably connected, to terminal DIAG_HS_600. Resistor R602 includes a first terminal coupled, preferably connected, to node N601, and a second terminal coupled, preferably connected, to terminal SGND_600.

FIG. 7 illustrates a simplified embodiment of a voltage shifter circuit 700 of a converter of the type of the converters described in connection with FIGS. 4 to 6.

FIG. 7 illustrates the embodiment of the voltage shifter circuit 700, a power transistor T701, and a gate driver D701 (DRIVER) for the power transistor T701.

As previously described, a drain terminal of power transistor T701 is coupled, preferably connected, to a terminal DRAIN_700, a drain terminal of power transistor T701 is coupled, preferably connected, to a terminal DRAIN_700, and a source terminal of power transistor T701 is coupled, preferably connected, to a terminal SOURCE_700. A gate terminal of transistor T701 receives a control voltage from gate driver circuit D701.

The voltage shifter circuit 700 includes an outer voltage source Supp701 coupled between terminals VCC_HS_701 and OUT_K_700. A positive terminal of the source Supp701 is coupled, preferably connected, to the terminal VCC_HS_700, and a negative terminal of the source Supp701 is coupled, preferably connected, to the terminal OUT_K_700.

The voltage shifter circuit 700 further includes a resistor R701 and an inverter circuit INV701. A first terminal of the resistor R701 is coupled, preferably connected, to the terminal VCC_HS_700, and a second terminal of the resistor R701 is coupled, preferably connected, to a node N701. An input terminal of the inverter circuit INV701 is coupled, preferably connected, to the node N701, and an output terminal of the inverter circuit INV701 is coupled, preferably connected, to an input of the gate driver circuit D701.

The voltage shifter circuit 700 further includes two current sources CS701 and CS702. Current source CS701 is referenced to terminal SGND_700, and includes an output coupled, preferably connected, to node N701. Current source CS702 is referenced to terminal OUT_700, and includes an output coupled, preferably connected, to node N701. Current sources CS701 and CS702 are controlled by the potential supplied by terminal IN_HS_700.

The operating principle of the circuit 700 is as follows. Current sources CS701 and CS702 are used to send commands to gate driver circuit D701, and ultimately to transistor T701. However, the converter can operate at very high voltage, and the converter output voltage, i.e., the voltage supplied between terminals OUT_700 and SGND_700, can be between −50 and 650 V, preferably between −15 and 500 V. Current sources CS701 and CS702 do not supply currents of the same intensity. When the output voltage is above a threshold voltage, only the current source CS701 is used, and when the output voltage is below this threshold voltage, the other current source, i.e., the current source CS702, is used. According to one example, the threshold voltage is between −5 and 0 V. According to one example, when the output voltage is above −2 V, current source CS701 is used to transmit commands to circuit D701, and when the output voltage is below −2 V, current source CS702 is used to transmit commands to circuit D701.

FIG. 8 illustrates a more detailed embodiment of a voltage shifter circuit 800 in a converter of the type of the converters described in connection with FIGS. 4 to 6.

Voltage shifter circuit 800 is of the type of voltage shifter circuit 526 described in connection with FIG. 5, and is formed astride two chips of the type of chips 510 and 520. More particularly, the circuit portions (A) and (B) delimited by dotted lines are formed in a chip suitable for receiving low voltages, hereinafter referred to as a low-voltage chip, of the type of chip 402 described in connection with FIG. 4, or of the type of chip 520 described in connection with FIG. 5, the remainder of the components being formed in a chip suitable for receiving high voltages, hereinafter referred to as a high-voltage chip, of the type of chip 401 described in connection with FIG. 4 or of the type of chip 510 described in connection with FIG. 5. Interconnection terminals 810 of the high-voltage and low-voltage chips are also illustrated in FIG. 8.

According to a first example, illustrated in FIG. 8, the low-voltage and high-voltage chips can be coupled by three sets of interconnection terminals 810.

According to a second example, not illustrated in FIG. 8, the low-voltage and high-voltage chips can be coupled by only two sets of interconnection terminals 810. An advantage of this example is that it allows the size of the substrates on which the high-voltage and low-voltage chips are formed to be reduced. In this case, by way of example, the transistors T805 to T807 described hereinafter form part of the low-voltage chip.

Circuit 800 includes:
a terminal VCC_HS_800 of the type of the terminal VCC_HS_500 described in connection with FIG. 5, or of the type of the terminal VCC_HS_700 described in connection with FIG. 7, the terminal VCC_HS_800 forming a supply terminal for the high-voltage chip;
a terminal SGND_HS_800 of the type of the terminal OUT_K_500 described in connection with FIG. 5, the terminal SGND_HS_800 forming a reference terminal of the high-voltage chip;
a terminal SGND_LS_800 of the type of the terminal SGND_500 described in connection with FIG. 5, or of the type of the terminal SGND_700 described in connection with FIG. 7, the terminal SGND_LS_800 forming a reference terminal of the low-voltage chip;
a terminal DZ_HS_800 of the type of the terminal DZ_HS_500 described in connection with FIG. 5;
a terminal DZ_LS_800 of the type of the terminal DZ_LS_500 described in connection with FIG. 5; and
a terminal PWM_800 (SOURCE).

Circuit 800 further includes, between terminals VCC_HS_800 and SGND_LS_800, three resistors T801, R802 and R803, and two HEMT transistors T801 and T802 of the e-mode type. A first terminal of resistor R801 is coupled, preferably connected, to terminal VCC_HS_800, and a second terminal of resistor R801 is coupled, preferably connected, to a first terminal of resistor R802. A second terminal of resistor R802 is coupled, preferably connected, to a drain terminal of transistor T801. A source terminal of transistor T801 is coupled, preferably connected, to a drain terminal of transistor T802. A source terminal of transistor T802 is coupled, preferably connected, to a first terminal of resistor R803. A second terminal of resistor R803 is coupled, preferably connected, to terminal SGND_LS_800. A gate terminal of transistor T801 is coupled, preferably connected, to terminal DZ_LS_800.

Circuit 800 further includes a pulse width modulation circuit PWM801. An input of this circuit PWM801 is suitable for receiving a control signal supplied by the terminal PWM_800 which has been inverted. An output of this circuit PWM801 is coupled, preferably connected, to the gate terminal of transistor T802.

Circuit 800 further includes four e-mode-type HEMT transistors T803, T804, T805 and T806, two resistors R804 and R805, and a voltage source Supp801. A source terminal of transistor T803 is coupled, preferably connected, to terminal DZ_LS_800, and a drain terminal of transistor T803 is coupled, preferably connected, to a first terminal of resistor R804. A second terminal of resistor R804 is coupled, preferably connected, to a drain terminal of transistor T805 and to a gate terminal of transistor T805. A source terminal of transistor T804 is coupled, preferably connected, to terminal DZ_LS_800, and a drain terminal of transistor T804 is coupled, preferably connected, to a first terminal of resistor R805. A second terminal of resistor R805 is coupled, preferably connected, to a drain terminal of transistor T806 and to a gate terminal of transistor T806. The source terminals of transistors T805 and T806 are coupled to each other, and to the terminal SGND_HS_800. One gate terminal of the transistor receives a voltage from voltage source Supp801. Voltage source Supp801 is referenced to terminal SGND_LS_800. A gate terminal of transistor T804 is coupled, preferably connected, to terminal PWM_800.

Circuit 800 further includes an e-mode-type HEMT transistor. A source terminal of transistor T807 is coupled, preferably connected, to terminal SGND_HS_800. A gate terminal of transistor T807 is coupled to the drain terminal of transistor T806. Transistor T807 is suitable for supplying a current, and is regarded as an output of a current source. According to one embodiment, transistor T807 forms an output of the current source CS702 described in connection with FIG. 7.

Circuit 800 further includes, between terminals VCC_HS_800 and SGND_LS_800, three resistors R806, R807, and R808, and two e-mode-type HEMT transistors T808 and T809. A first terminal of resistor R806 is coupled, preferably connected, to terminal VCC_HS_800, and a second terminal of resistor R806 is coupled, preferably connected, to a first terminal of resistor R807. A second terminal of resistor R807 is coupled, preferably connected, to a drain terminal of transistor T808. A source terminal of transistor T808 is coupled, preferably connected, to a drain terminal of transistor T809. A source terminal of transistor T809 is coupled, preferably connected, to a first terminal of resistor R808. A second terminal of resistor R808 is coupled, preferably connected, to terminal SGND_LS_800. A gate terminal of transistor T808 is coupled, preferably connected, to terminal DZ_LS_800. Transistors T808 and T809 are suitable for supplying a current, and are regarded as an output of a current source. According to one embodiment, transistors T808 and T809 form an output of the current source CS701 described in connection with FIG. 7.

Circuit 800 further includes a pulse-width modulation circuit PWM802. An input of this circuit PWM802 is suitable for receiving a control signal supplied by the terminal PWM_800. An output of this circuit PWM802 is coupled, preferably connected, to the gate terminal of transistor T809.

Circuit 800 further includes a flip-flop L801 (LATCH) of the type of flip-flop L601 described in connection with FIG. 6, two resistors R809 and R810, and two e-mode-type HEMT transistors T810 and T811. A first terminal of resistor R809 is coupled, preferably connected, to terminal DZ_HS_800, and a second terminal of resistor R809 is coupled, preferably connected, to an input terminal of flip-flop L801 and to a drain terminal of transistor T810. A source terminal of transistor T810 is coupled, preferably connected, to terminal SGND_HS_800. A gate terminal of transistor T810 is coupled, preferably connected, to the second terminal of resistor R806, i.e., to the drain terminal of transistor T807. A first terminal of resistor R810 is coupled, preferably connected, to terminal DZ_HS_800, and a second terminal of resistor R810 is coupled, preferably connected, to a first output terminal of flip-flop L801 and to a drain terminal of transistor T811. A source terminal of transistor T811 is coupled, preferably connected, to terminal SGND_HS_800. A gate terminal of transistor T811 is coupled, preferably connected, to the second terminal of resistor R801. A second output terminal of flip-flop L801 is suitable for supplying a control voltage to a gate driver circuit of the type of circuit D701 described in connection with FIG. 7.

FIG. 9 illustrates a more detailed embodiment of a voltage adapter circuit 900 of a converter of the type of converters described in connection with FIGS. 4 to 6.

The voltage adapter circuit 900 is of the type of adapter circuit 515 described in connection with FIG. 5, and more particularly a converter circuit of the type of adapter circuit ADAPT601 described in connection with FIG. 6.

Voltage adapter circuit 900 is of the type of voltage adapter circuit 515 described in connection with FIG. 5, and is formed astride two chips of the type of chips 510 and 520. More particularly, the circuit portions 920 are formed in a chip suitable for receiving low voltages, hereinafter referred to as low-voltage chip, of the type of chip 402 described in connection with FIG. 4, or of the type of chip 520 described in connection with FIG. 5, the remainder of the components, referenced 910 is formed in a chip suitable for receiving high voltages, hereinafter referred to as high-voltage chip, of the type of chip 401 described in connection with FIG. 4, or of the type of chip 510 described in connection with FIG. 5.

Circuit 900 includes:
a terminal DZ_HS_900 of the type of the terminal DZ_HS_500 described in connection with FIG. 5;
a terminal DZ_LS_900 of the type of the terminal DZ_LS_500 described in connection with FIG. 5;
a terminal OUT_K_900 of the type of the terminal OUT_K_500 described in connection with FIG. 5;
a terminal SGND_LS_900 of the type of the terminal SGND_500 described in connection with FIG. 5;
a terminal IN_HS_900 of the type of the terminal IN_HS_500 described in connection with FIG. 5; and
a terminal DIAG_HS_900 of the type of the terminal DIAG_HS_500 described in connection with FIG. 5.

Circuit 900 includes an oscillator OSC901 (OSC), or oscillating circuit OSC901, a logic gate OR901, and an inverter circuit INV901. The oscillator OSC901 is supplied by a potential provided by the terminal DZ_HS_900, and is referenced to a potential provided by the terminal OUT_K_900. A control terminal of the oscillator OSC901 is coupled, preferably connected, to the output of the logic gate OR901. A first input terminal of the logic gate OR901 is suitable for receiving an overvoltage detection voltage VDS_HS_900. A second input terminal of the logic gate OR901 is suitable for receiving an overtemperature detection voltage OT_HS_900. An output of the oscillator OSC901 is coupled, preferably connected, to an input of the inverter circuit INV901. The inverter circuit INV901 is supplied by a potential provided by the terminal DZ_HS_900, and is referenced to a potential provided by the terminal OUT_K_900.

Circuit 900 further includes a capacitor C901, an e-mode-type HEMT transistor T901, and a resistor R901. A first terminal of the capacitor C901 is coupled, preferably connected, to the output of the inverter circuit INV901, and a second terminal of the capacitor C901 is coupled, preferably connected, to a drain terminal of transistor T901. A source terminal of transistor T901 is coupled, preferably connected, to a first terminal of resistor R901. A second terminal of resistor R901 is coupled, preferably connected, to terminal SGND_LS_900. A gate terminal of transistor T901 is coupled, preferably connected, to terminal DZ_LS_900.

Circuit 900 further includes two e-mode-type HEMT transistors T902 and T904, and a resistor R902. A drain terminal of transistor T902 is coupled, preferably connected, to terminal VCC_LS_900, and a source terminal of transistor T902 is coupled, preferably connected, to a first terminal of resistor R902. A second terminal of resistor R902 is coupled, preferably connected, to the drain terminal of transistor T904. A source terminal of transistor T904 is coupled, preferably connected, to terminal SGND_LS_900.

Circuit 900 further includes an inverter circuit INV902. An input of circuit INV902 is coupled, preferably connected, to the drain terminal of transistor T904. An output terminal of the circuit INV902 is coupled, preferably connected, to the terminal DIAG_HS_900.

Circuit 900 further includes a transistor T903, a capacitor C902, and a resistor R903. A drain terminal of transistor T903 is coupled, preferably connected, to the source terminal of transistor T901, and a drain terminal of transistor T903 is coupled, preferably connected, to terminal SGND_LS_900. The gate terminal of transistor T903 is coupled, preferably connected, to a first terminal of capacitor C902. A second terminal of capacitor C902 is coupled, preferably connected, to terminal SGND_LS_900. A first terminal of resistor R903 is coupled, preferably connected, to the gate of transistor T903, and a second terminal of resistor R903 is coupled, preferably connected, to terminal IN_HS_900.

The circuit 900 operates as follows. Oscillator OSC901 receives, as input, a fault detection signal obtained from voltages VDS_HS_900 and OT_HS_901, and outputs an oscillating signal. More specifically, when the fault detection signal is in a first state, e.g., a high state, the oscillator OSC901 outputs an oscillating signal, or oscillating voltage, and when the fault detection signal is in a second state, different from the first state, e.g., a low state, the oscillator OSC901 outputs a constant signal, i.e., a signal that does not exhibit oscillation.

More specifically, the key element of circuit 900 is capacitor C901, and it is this capacitor C901 that forwards information by capacitive coupling from the high-voltage chip to the low-voltage chip. Information forwarding is achieved with a low-voltage differential voltage, for example of the order of 6 V, on a common-mode voltage of 400 V. In addition, according to one embodiment, capacitor C901 is formed in and on the low-voltage chip, between metallization levels, for example between the second and third metallization levels.

FIG. 10 illustrates very schematically and under block form an embodiment of a converter 1000 of the type of converters described in connection with FIGS. 4 to 6.

As described in connection with FIG. 4, the converter 1000 includes two chips 1010 (Die HS) and 1020 (Die LS) using structures including gallium nitride (GaN), such as a structure of the type of structure 100 described in connection with FIG. 1.

According to one embodiment, chips 1010 and 1020 are identical, i.e., they have been manufactured using the same manufacturing method, and have been manufactured on the same structure. In other words, chips 1010 and 1020 include the same electronic circuits and components. Only the placement of the components may differ from one chip to the other. In addition, according to one embodiment, both chips 1010 and 1020 are suitable for being a high-voltage chip or a low-voltage chip.

Each chip 1010, 1020 includes a main terminal, denoted D for chip 1010 and S for chip 1020, and a communication terminal OUT. According to one embodiment, the chips 1010 and 1020 each include a configuration terminal CONFIG used to define the function of each chip. In particular, the terminal CONFIG can be used to configure a chip 1010, 1020 as a high-voltage chip or as a low-voltage chip.

According to the example illustrated in FIG. 10, each chip 1010, 1020 further includes the following terminals:
a terminal ON_HS_LS;
a terminal OFF_HS_LS;
a terminal RST_HS_LS;
a terminal DIAG_HS_LS;
a terminal RST_HS_LS;
a terminal OFF_HS_HS;
a terminal ON_HS_HS;
a terminal VCC;
a terminal VDD;
a terminal DZ;
a terminal EN;
a terminal PWM;
a terminal RST;
a terminal DIAG; and
a terminal SGND.

To form the converter 1000, the chips 1010 and 1020 are mounted on the same wafer. Other electronic components can be added to the substrate, as described in connection with FIG. 5.

Chips 1010 and 1020 are coupled to each other, for example by coupling their communication terminals OUT to each other. According to one example, the terminals ON_HS_LS of chips 1010 and 1020 are also coupled to each other. According to one example, the terminals OFF_HS_LS of chips 1010 and 1020 are also coupled to each other. According to one example, the terminals RST_HS_LS of chips 1010 and 1020 are also coupled to each other. According to one example, the terminals DIAG_HS_LS of chips 1010 and 1020 are also coupled to each other.

Connection terminals of the converter 1000 are further coupled to the terminals of the chips 1010 and 1020. According to one example:
a terminal VCC_HS of the converter 1000 is coupled, preferably connected, to the terminal VCC of the chip 1010;
a terminal VDD_HS of the converter 1000 is coupled, preferably connected, to the terminal VDD of the chip 1010;
a terminal DZ_HS of the converter 1000 is coupled, preferably connected, to the terminal DZ of the chip 1010;
a terminal SGND_HS of the converter 1000 is coupled, preferably connected, to the terminal SGND of the chip 1010;
a terminal VCC_LS of the converter 1000 is coupled, preferably connected, to the terminal VCC of the chip 1020;
a terminal VDD_LS of the converter 1000 is coupled, preferably connected, to the terminal VDD of the chip 1020;
a terminal DZ_LS of the converter 1000 is coupled, preferably connected, to the terminal DZ of the chip 1020;
a terminal EN of the converter 1000 is coupled, preferably connected, to the terminal EN of the chip 1020;
a terminal PWM of the converter 1000 is coupled, preferably connected, to the terminal PWM of the chip 1020;
a terminal RST of the converter 1000 is coupled, preferably connected, to the terminal RST of the chip 1020;
a terminal DIAG of the converter 1000 is coupled, preferably connected, to the terminal DIAG of the chip 1020; and
a terminal SGND_LS of the converter 1000 is coupled, preferably connected, to the terminal SGND of the chip 1020.

Thus, a method for manufacturing the converter 1000 includes two identical manufacturing steps for the first and second chips. According to one example, the method further includes a configuration step using the terminals CONFIG of chips 1010 and 1020.

Various embodiments and variants have been described. Those skilled in the art will understand that certain features of these embodiments can be combined and other variants will readily occur to those skilled in the art.

Finally, the practical implementation of the embodiments and variants described herein is within the capabilities of those skilled in the art based on the functional description provided hereinabove.

A voltage converter (400; 500; 600; 1000) formed in and on a monolithic semiconductor substrate (101) having a face coated by a gallium nitride layer (102), includes a first chip (401; 510; 1010) including a first e-mode-type HEMT power transistor (T401; T510; T601), and a first control circuit (D401) of the first transistor (T401; T510; T601); and a second chip (402; 520; 1020) including a second e-mode-type HEMT power transistor (T402; T520; T602), and a second control circuit (D402) of the second transistor (T402; T520; T602), and being suitable for forwarding at least one first voltage received from a third control circuit (410; 550) to the second chip (402; 520; 1020); wherein the second chip (402; 520; 1020) includes a first voltage shifter circuit (526; ADAPT601; 700) suitable for converting the at least one first voltage into a second voltage, the first voltage shifter circuit (526; LS601; 700) includes a first current source (CS701) suitable for being used when a third output voltage of the converter (400; 500; 600; 1000) is less than a fourth threshold voltage, and a second current source (CS702) suitable for being used when the third output voltage is higher than the fourth threshold voltage.
the first and second current sources (CS701, CS702) are used to provide a control voltage to the first transistor (T401; T510; T601).

The fourth threshold voltage is between −5 and 0 V.

The fourth threshold voltage is equal to −2 V.

The first chip (401; 510; 1010) is suitable for receiving high voltages, and the second chip (402; 520; 1020) is suitable for receiving low voltages.

The first chip (401; 510; 1010) further includes a fourth voltage adapter circuit (515; CONV601; 900) suitable for converting at least one fifth voltage of the first chip (401; 510; 1010) into a sixth diagnosis voltage to forward it to the second chip (402; 520; 1020), the fourth voltage adapter circuit (515; ADAPT601; 900) includes an oscillator (OSC601; OSC901) being configured to oscillate the sixth voltage when the fifth voltage is at a first state.

The oscillator (OSC601; OSC901) is configured not to oscillate the sixth voltage when fifth voltage is at a second state different from the first state.

The first and second chips (401, 402; 510, 520; 1010, 1020) are identical chips.

The first and second chips (401, 402; 510, 520; 1010, 1020) include each a configuration terminal (CONFIG) allowing them to define their function in the converter.

The converter being a switched-mode power supply.

The converter being a switched-mode power supply of the boost-converter type

A method for converting a seventh input voltage into a third output voltage using a voltage converter (400; 500; 600; 1000) formed in and on a monolithic semiconductor substrate (101) having a face coated by a gallium nitride layer (102), includes a first chip (401; 510; 1010) including a first e-mode-type HEMT power transistor (T401; T510; T601), and a first control circuit (D401) of the first transistor (T401; T510; T601); and a second chip (402; 520; 1020) including a second e-mode-type HEMT power transistor (T402; T520; T602), and a second control circuit (D402) of the second transistor (T402; T520; T602), and being suitable for forwarding at least one first voltage received from a third control circuit (410; 550) to the second chip (402; 520; 1020); wherein the second chip (402; 520; 1020) includes a first voltage converter circuit (526; ADAPT601; 700) suitable for converting the at least one first voltage into a second voltage, the first voltage converter circuit (526; LS601; 700) includes a first current source (CS701) suitable for being used when a third output voltage of the converter (400; 500; 600; 1000) is less than a fourth threshold voltage, and a second current source (CS702) suitable for being used when the third output voltage is higher than the fourth threshold voltage.

The method for manufacturing a voltage converter (400; 500; 600; 1000), includes: a first chip (401; 510; 1010) including a first e-mode-type HEMT power transistor (T401; T510; T601), and a first control circuit (D401) of the first transistor (T401; T510; T601); and a second chip (402; 520; 1020) including a second e-mode-type HEMT power transistor (T402; T520; T602), and a second control circuit (D402; 521; D602) of the second transistor (T402; T520; T602), including two identical steps of manufacturing the first and second chips (401, 402; 510, 520; 1010, 1020).

The method further includes a step of configuring the first and second chips (401, 402; 510, 520; 1010, 1020) which follows the two manufacturing steps.

During the configuring step, a configuration terminal (CONFIG) of the first and second chips (401, 402; 510, 520; 1010, 1020) is used.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A voltage converter formed in and on a monolithic semiconductor substrate having a face coated by a gallium nitride layer, the voltage converter comprising:
a first chip including a first e-mode-type HEMT power transistor, and a first control circuit of the first transistor; and
a second chip including a second e-mode-type HEMT power transistor, and a second control circuit of the second transistor, and configured to forward at least one first voltage received from a third control circuit to the second chip;
wherein the second chip includes a first voltage shifter circuit suitable for converting the at least one first voltage into a second voltage,
the first voltage shifter circuit including a first current source configured to operate when a third output voltage of the converter is less than a fourth threshold voltage, and a second current source configured to operate when the third output voltage is higher than the fourth threshold voltage.

2. The converter according to claim 1, wherein the first and second current sources are used to provide a control voltage to the first transistor.

3. The converter according to claim 1, wherein the fourth threshold voltage is between −5 and 0 V.

4. The converter according to claim 3, wherein the fourth threshold voltage is equal to −2 V.

5. The converter according to claim 1, wherein the first chip is configured to receive high voltages, and the second chip is configured to receive low voltages.

6. The converter according to claim 1, wherein the first chip further includes a fourth voltage adapter circuit configured to convert at least one fifth voltage of the first chip into a sixth diagnosis voltage to forward it to the second chip,
the fourth voltage adapter circuit including an oscillator being configured to oscillate the sixth voltage when the fifth voltage is at a first state.

7. The converter according to claim 6, wherein the oscillator is configured not to oscillate the sixth voltage when the fifth voltage is at a second state different from the first state.

8. The converter according to claim 1, wherein the first and second chips are identical chips.

9. The converter according to claim 8, wherein the first and second chips comprise each a configuration terminal allowing them to define their function in the converter.

10. The converter according to claim 1, being a switched-mode power supply.

11. The converter according to claim 1, being a switched-mode power supply of the boost-converter type.

12. A method, comprising:
driving a first HEMT power transistor of a first chip with a first control circuit of the first chip of a voltage converter;
driving a second HEMT power transistor of a second chip with a second control circuit of the second chip of the voltage converter, the first and second HEMT power transistor being coupled together in a half bridge configuration, wherein the first chip is a high side chip and the second chip is a low side chip;
receiving, with the second chip, first control signals for the first chip from a third control circuit external to the first and second chips;
receiving, with the second chip, second control signals for the second chip from the third control circuit;
providing the first control signals from the second chip to the first chip;
receiving an input voltage of the voltage regulator at the second chip; and
generating an output voltage of the voltage regulator at an output of the half bridge circuit.

13. The method of claim 12, comprising providing diagnostic signals from the first chip to the second chip.

14. The method of claim 13, further comprising providing the diagnostic signals from the second chip to the third control circuit.

15. The method of claim 12, further comprising receiving high voltages at the first chip and receiving low voltages at the second chip.

16. The method of claim 12, further comprising generating a first current with a first current source of the first chip.

17. The method of claim 16, further comprising generating a second current with a second current source of the first chip.

18. A method, comprising:
forming a first chip of a voltage converter, including:
forming a first HEMT power transistor in the first chip; and
forming a first driver circuit of the first HEMT transistor in the first chip;
forming a second chip of the voltage converter, including:
forming a second HEMT power transistor in the second chip; and
forming a second driver circuit of the second HEMT transistor in the second chip;
coupling the first and second HEMT transistors together in a half bridge configuration; and
coupling a third control circuit to the second chip and configured to provide to the second chip first control signals for the first chip, to provide second control signal to the second chip for controlling the second chip, and to provide an input voltage of the voltage regulator to the second chip, the voltage regulator configured to provide an output voltage of the voltage regulator from a joint terminal of the first and second HEMT transistors.

19. The method of claim 18, further comprising forming the first and second chips in two identical manufacturing steps.

20. The method according to claim 19, further comprising configuring the first and second chips following the two manufacturing steps.
